(19) United States
(12) Patent Application Publication
(10) Pub. No.: US 2025/0299997 A1
(43) Pub. Date: Sep. 25, 2025

(54) METHOD FOR MANUFACTURING SEMICONDUCTOR DEVICE

(71) Applicant: Resonac Corporation, Minato-ku, Tokyo (JP)

(72) Inventors: Yuki MIYAMOTO, Minato-ku, Tokyo (JP); Tomohito MOROSAKI, Minato-ku, Tokyo (JP); Katsuhiko SUZUKI, Minato-ku, Tokyo (JP); Masayuki WADA, Minato-ku, Tokyo (JP); Masahito WATANABE, Minato-ku, Tokyo (JP); Keiichi SAKAMOTO, Minato-ku, Tokyo (JP); Hidekazu KONDO, Minato-ku, Tokyo (JP); Koichi SAITO, Minato-ku, Tokyo (JP)

(21) Appl. No.: 18/860,805

(22) PCT Filed: Oct. 6, 2023
(86) PCT No.: PCT/JP2023/036618

§ 371 Date: Oct. 28, 2024

(30) Foreign Application Priority Data
Oct. 11, 2022 (JP) 2022-163401

(51) Int. Cl. H01L 21/683; C09J 5/00; C09J 181/04; H01L 21/304; H01L 21/78

(52) U.S. Cl. CPC H01L 21/6836; C09J 5/00; C09J 181/04; H01L 21/304; H01L 21/78; C09J 2203/326; C09J 2481/00; H01L 2221/68327

(57) ABSTRACT

A method for manufacturing a semiconductor device is disclosed. The method for manufacturing a semiconductor device includes a first laminated body manufacturing step of manufacturing a first laminated body including, in this order, a semiconductor wafer, a resin layer containing a resin in which the molecular weight is reduced by irradiation with light, and a base material layer; a second laminated body manufacturing step of manufacturing a second laminated body by performing backside grinding on the semiconductor wafer of the first laminated body; and a third laminated body manufacturing step of manufacturing a third laminated body including a semiconductor wafer subjected to backside grinding and the resin layer by removing the base material layer of the second laminated body.

### TECHNICAL FIELD

The present disclosure relates to a method for manufacturing a semiconductor device.

### BACKGROUND ART

In the manufacturing of a semiconductor device, a backside grinding (back grinding) step of forming a pattern on one face (surface, circuit formation surface) of a semiconductor wafer and grinding the other face (back surface) of the semiconductor wafer with a back grinder or the like until a predetermined thickness is obtained is generally performed. In a backside grinding step, for the purpose of protecting the semiconductor wafer, a back grinding tape is generally bonded to the semiconductor wafer to grind the back surface (for example, Patent Literature 1).

### CITATION LIST

### Patent Literature

Patent Literature 1: JP 2010-034379 A

### SUMMARY OF INVENTION

### Technical Problem

An object of the present disclosure is to provide a novel method for manufacturing a semiconductor device including performing backside grinding on a semiconductor wafer.

### Solution to Problem

The present disclosure provides methods for manufacturing a semiconductor device of [1] to [3].
[1] A method for manufacturing a semiconductor device includes a first laminated body manufacturing step of manufacturing a first laminated body including, in this order, a semiconductor wafer, a resin layer containing a resin in which the molecular weight is reduced by irradiation with light, and a base material layer; a second laminated body manufacturing step of manufacturing a second laminated body by performing backside grinding on the semiconductor wafer of the first laminated body; and a third laminated body manufacturing step of manufacturing a third laminated body including a semiconductor wafer subjected to backside grinding and the resin layer by removing the base material layer of the second laminated body.
[2] The method for manufacturing a semiconductor device according to [1], in which the third laminated body manufacturing step is irradiating the resin layer of the second laminated body with light to remove the base material layer.
[3] The method for manufacturing a semiconductor device according to [1] or [2], further including dicing the third laminated body to manufacture a singulated resin layer piece-including semiconductor chip.

### Advantageous Effects of Invention

According to the present disclosure, a novel method for manufacturing a semiconductor device including performing backside grinding on a semiconductor wafer is provided. According to the method for manufacturing a semiconductor device of the present disclosure, a semiconductor wafer can be sufficiently protected, and a base material layer can be easily removed.

### BRIEF DESCRIPTION OF DRAWINGS

FIG. 1 is a schematic cross-sectional view illustrating an embodiment of a method for manufacturing a semiconductor device, and FIGS. 1(a), 1(b), 1(c), 1(d), and 1(e) are views illustrating respective steps.

FIG. 2 is a schematic cross-sectional view illustrating an embodiment of the method for manufacturing a semiconductor device, and FIGS. 2(a), 2(b), 2(c), and 2(d) are views illustrating respective steps.

FIG. 3 is a schematic cross-sectional view illustrating an embodiment of the method for manufacturing a semiconductor device, and FIGS. 3(a), 3(b), 3(c), and 3(d) are views illustrating respective steps.

### DESCRIPTION OF EMBODIMENTS

Hereinafter, the present embodiment is described in detail with reference to the drawings. However, the present disclosure is not limited to the following embodiments. In the following embodiments, the components (including steps and the like) are not essential unless otherwise specified. The same or corresponding portions are denoted by the same reference numerals, and redundant description will be omitted. Further, unless otherwise specified, the positional relationship such as up, down, left, and right is based on the positional relationship illustrated in the drawings. The sizes of components in the drawings are conceptual, and the relative relationship between the sizes of the components is not limited to that illustrated in the drawings.

The same applies to numerical values and ranges thereof in the present disclosure, and the present disclosure is not limited thereto. In the present specification, a numerical range indicated by using “to” indicates a range including numerical values described before and after “to” as a minimum value and a maximum value, respectively. In the numerical ranges described in stages in the present specification, the upper limit value or the lower limit value described in one numerical range may be replaced with the upper limit value or the lower limit value of the numerical range described in another stage. In addition, in the numerical range described in the present specification, the upper limit value or the lower limit value of the numerical range may be replaced with a value shown in examples.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved.

In the present specification, (meth)acrylate means acrylate or methacrylate corresponding thereto. The same applies to other similar expressions such as a (meth)acrylic copolymer.

The components and materials exemplified in the present specification may be used singly or in combination of two or more kinds thereof unless otherwise specified.

### [Method for Manufacturing Semiconductor Device]

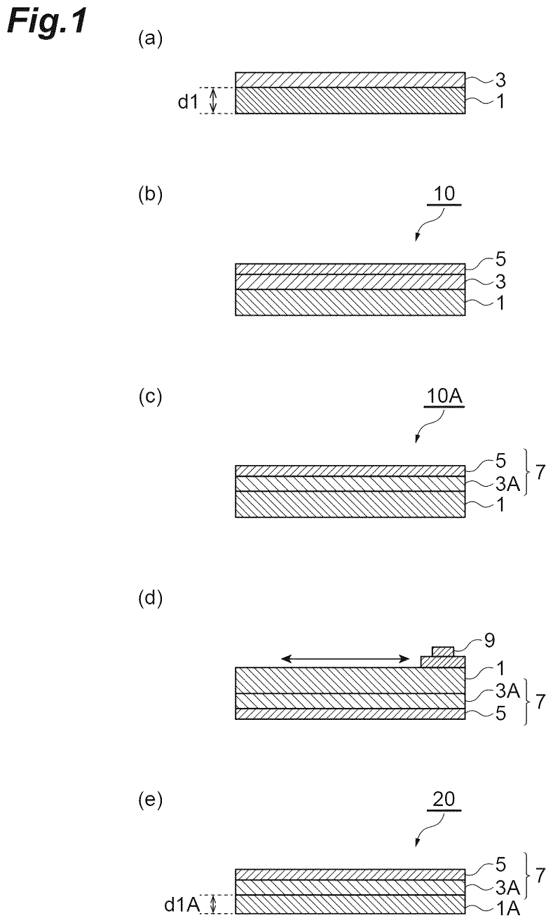

A method for manufacturing a semiconductor device according to an embodiment relates to a method for manufacturing a semiconductor device including performing backside grinding on a semiconductor wafer. The method for manufacturing a semiconductor device includes a first laminated body manufacturing step, a second laminated body manufacturing step, and a third laminated body manufacturing step. The method for manufacturing a semiconductor device may further include a resin layer piece-including semiconductor chip manufacturing step. FIGS. 1, 2, and 3 are schematic cross-sectional views illustrating an embodiment of the method for manufacturing a semiconductor device.

### <First Laminated Body Manufacturing Step>

In this step, a first laminated body 10A including a semiconductor wafer 1, a resin layer 3A containing a resin in which the molecular weight is reduced by irradiation with light (hereinafter, referred to as a “light meltable resin”), and a base material layer 5 are manufactured in this order. The light meltable resin may be a resin having properties such as deterioration of an elastic modulus and an increase in a loss tangent (tan δ) due to the reduction of the molecular weight by irradiation with light. The light meltable resin is a water-insoluble resin and may be a resin having properties in which the molecular weight is reduced due to the irradiation with light to obtain a water-soluble gel or liquid.

In one embodiment, the light meltable resin may be a reaction product of a compound A having a disulfide bond and two or more thiol groups and a compound B having two or more functional groups capable of reacting with a thiol group. The resin layer 3A may further contain a photoradical generator in addition to the light meltable resin. The resin layer 3A can be formed, for example, by arranging, at a predetermined position, a curable composition containing the compound A, the compound B, the photoradical generator, and, as necessary, a curing accelerator that accelerates the reaction between the compound A and the compound B and curing the curable composition by heating or light irradiation (reacting the compound A and the compound B). At this time, it can be said that the resin layer 3A contains a cured product of the curable composition containing the compound A, the compound B, the photoradical generator, and, as necessary, the curing accelerator that accelerates the reaction of the compound A and the compound B. It can be said that the cured product of the curable composition contains a reaction product of the compound A and the compound B and a photoradical generator. The curable composition may be a thermosetting composition that is cured by heating or a photocurable composition that is cured by light irradiation and may be a thermosetting composition according to an embodiment.

According to an embodiment, the curable composition may contain the compound A, the compound B, the photoradical generator, and, as necessary, the curing accelerator that accelerates the reaction of the compound A and the compound B.

### (Compound A)

The compound A is a compound having a disulfide bond (—S—S—) and having two or more thiol groups (—SH). The upper limit of the number of thiol groups in the compound A may be, for example, ten or less, eight or less, six or less, or four or less. A component (A) may be, for example, a dithiol compound which is a compound having two thiol groups (—SH). The component (A) may be a high molecular weight component of a polymer or an oligomer. A compound having two thiol groups (—SH) can be regarded as a compound containing two thiol groups and a group containing a disulfide bond and linking the two thiol groups (first linking group).

The molecular weight or number average molecular weight of the compound A may be, for example, 100 to 10,000,000, 200 to 3,000,000, 300 to 1,000,000, 400 to 10,000, or 500 to 5,000. Note that the number average molecular weight is a value in terms of polystyrene using a calibration curve by standard polystyrene by gel permeation chromatography (GPC).

The compound A has one or more (two or more) disulfide bonds in the molecule. The number of disulfide bonds in the compound A may be, for example, 1 to 1,000 or 4 to 50.

The compound A may be a compound having a linear or branched molecular chain and a terminal group and having a disulfide bond in the molecular chain (for example, polymers or oligomers). In this case, the terminal group in the compound A may be a thiol group. When the curable composition contains such a compound as the compound A, the light meltability of the light meltable resin (a reaction product of the compound A and the compound B) tends to be further improved. The molecular chain in the compound A may contain a disulfide bond and a polyether chain or may consist of a disulfide bond and a polyether chain.

The compound A may be, for example, a compound represented by Formula (1): HS—(X—S—S)ₙ₁—X—SH (the compound (1)). In the formula, X represents a polyether chain. A plurality of Xs may be the same as or different from each other. n1 represents an integer of 1 or more. n1 may be, for example, 1 or more or 4 or more or may be 1,000 or less. When the component (A) is a compound represented by Formula (1), a group represented by —(X—S—S)ₙ₁—X— is a first linking group. The compound obtained by extending the chain of the compound (1) may be, for example, a Michael adduct of the compound (1) or a thiourethanized product of the compound (1).

The polyether chain as X may be, for example, a polyoxyalkylene chain. The polyether chain as X may be, for example, a group represented by —X¹—O—X²—O—X³—. X¹ to X³ may each independently be an alkylene group or an alkylene group having one to two carbon atoms (for example, a methylene group or an ethylene group). Examples of the polyether chain as X include —CH₂CH₂—O—CH₂—O—CH—CH₂—.

Examples of commercially available products of the compound A include Thiokol LP series (dithiol having a disulfide bond, manufactured by Toray Fine Chemicals Co., Ltd.). The compound A can also be obtained by converting a reactive functional group of a compound having a reactive functional group (for example, a carboxy group or a hydroxy group) and a disulfide bond at the terminal into a thiol group. Examples of the compound having a reactive functional group and a disulfide bond at the terminal include 3,3′-dithiodipropionic acid (manufactured by Tokyo Chemical Industry Co., Ltd.), dithiodiethanol, and cystamine.

The content of the compound A may be 15 mass % or more, 25 mass % or more, or 35 mass % or more and may be 80 mass % or less, 70 mass % or less, or 60 mass % or less, based on the total amount of the curable composition (solid content excluding the solvent).

### (Compound B)

The compound B is a compound having two or more functional groups capable of reacting with a thiol group. Examples of the functional group capable of reacting with a thiol group include a cyclic ether group (an oxirane group (an oxiranyl group, an epoxy group), an oxetane group (an oxetanyl group), a tetrahydrofuryl group, a tetrahydropyranyl group, and the like), an isocyanate group; an ethylenically unsaturated group (C═C). The upper limit of the number of functional groups in the compound B may be, for example, ten or less, eight or less, six or less, or four or less.

According to an embodiment, the compound B may be a compound B1 having a polyether chain and having two or more cyclic ether groups. When the curable composition contains the compound B1 as the compound B, the low molecular weight component generated by irradiating the light meltable resin with light has many polyether chains or many hydroxyl groups and tends to exhibit water solubility, so that the low molecular weight component can be removed with an aqueous solvent.

The cyclic ether group may be an oxirane group from the viewpoint of reactivity and availability. That is, the compound B1 is an oxirane compound (epoxy compound) having a polyether chain and having two or more oxirane groups (an oxiranyl group, an epoxy group). Note that in the present specification, the cyclic ether group includes a group having a cyclic ether structure (a structure containing a cyclic ether group). For example, the oxirane group includes a group having an oxirane structure such as a glycidyl group, a glycidyl ether group, or an epoxy cyclohexyl group (a structure containing an oxirane group (an oxiranyl group, an epoxy group)).

The molecular weight or number average molecular weight of the compound B1 may be, for example, 100 to 1,000,000, 100 to 500,000, 100 to 10,000, 150 to 5,000, or 200 to 2,000. Note that the number average molecular weight is a value in terms of polystyrene using a calibration curve by standard polystyrene by gel permeation chromatography (GPC).

When the cyclic ether group of the compound B1 is an oxirane group (an oxiranyl group, an epoxy group), the epoxy equivalent of the component (B) may be 50 to 2,000 g/eq, 80 to 1,500 g/eq, or 100 to 1,000 g/eq.

The compound B1 may be a compound B1a having two cyclic ether groups or a compound B1b having three or more cyclic ether groups. The compound B1a may be a compound having a linear molecular chain and a terminal group and having a polyether chain in the molecular chain (for example, polymers or oligomers). In this case, the terminal group in the compound B1a may be a cyclic ether group. The compound B1a can be regarded as a compound containing two cyclic ether groups and a group containing a polyether chain and linking the two cyclic ether groups (second linking group). The compound B1b may be a compound having one or more cyclic ether groups as a side chain or a substituent of the second linking group in the compound B1a. The compound B1 may contain both the compound B1a and the compound B1b because the compound can further shorten the curing time and can further improve the light meltability and water solubility.

The compound B1a may be a compound having a linear molecular chain and a terminal group and having a polyether chain in the molecular chain (for example, polymers or oligomers). In this case, the terminal group in the compound B1a may be a cyclic ether group. When the compound B is the compound B1a, a low molecular weight component generated by irradiating the light meltable resin with light tends to be easily removed with an aqueous solvent. The polyether chain as a molecular chain may have a substituent such as a hydroxyl group or an alkyl group which may have a hydroxyl group. The molecular chain in the compound B1a may contain a polyether chain or may consist of a polyether chain.

The compound B1a may be, for example, a compound represented by Formula (2): Z—(Y)ₙ₂—Z (the compound (2)). In the formula, Y represents a polyether chain, and Z represents a cyclic ether group. A plurality of Zs may be the same as or different from each other. n2 represents an integer of 1 or more. n2 may be, for example, 1 or more or 2 or more or may be 1,000 or less. When the compound B1a is the compound (2), the group represented by —(Y)ₙ₂— is the second linking group.

The polyether chain as Y may be, for example, a polyoxyalkylene chain. The polyether chain as Y may be, for example, a group represented by —Y¹—O—Y²—O—Y³—. Y¹ to Y³ may each independently be an alkylene group or an alkylene group having one to three carbon atoms (for example, a methylene group, an ethylene group, or a propylene group). Examples of the polyether chain as Y include —CH₂CH₂—O—CH₂—CH₂—O—CH₂CH₂—.

Examples of commercially available products of the compound B1a include Denacol EX series (EX-850, EX-851, EX-821, EX-830, EX-832, EX-841, EX-861, EX-920, manufactured by Nagase ChemteX Corporation).

The compound B1b may be a compound having one or more cyclic ether groups as a side chain of the second linking group (a polyether chain as Y) in the compound B1a.

Examples of commercially available products of the compound B1b include Denacol EX series (EX-614B, EX-313, EX-512, EX-521, manufactured by Nagase ChemteX Corporation).

The mass ratio of the content of the compound B1b to the total amount of the contents of the compound B1a and the compound B1b (a content (mass) of the compound B1b/a total amount (mass) of the contents of the compound B1a and the compound B1b) may be 0.01 to 0.40. When the mass ratio is 0.01 or more, the curing time of the curable composition tends to be further shortened, and when the mass ratio is 0.40 or less, the light meltability and the water solubility tend to be further improved. The mass ratio may be 0.02 or more or 0.03 or more and may be 0.35 or less, 0.30 or less, 0.25 or less, 0.20 or less, 0.15 or less, or 0.10 or less.

The content of the compound B may be 10 mass % or more, 20 mass % or more, or 30 mass % or more and may be 60 mass % or less, 50 mass % or less, or 40 mass % or less, based on the total amount of the curable composition (solid content excluding the solvent).

The ratio of the total number of moles of thiol groups in the compound A to the total number of moles of functional groups in the compound B may be, for example, 0.90 or more or 0.95 or more and may be 1.10 or less or 1.05 or less.

### (Photoradical Generator)

The photoradical generator is a component that generates radicals by light irradiation. As the photoradical generator, for example, a component used as a photopolymerization initiator can be used. Examples of the photoradical generator include an intramolecular cleavage type photoradical polymerization initiator in which the material itself is photocleaved by light irradiation to generate two radicals.

Examples of the intramolecular cleavage type photoradical generator include a benzyl ketal-based photoradical generator, an α-aminoalkylphenone-based photoradical generator, an α-hydroxyalkylphenone-based photoradical generator, an α-hydroxyacetophenone-based photoradical generator, and an acylphosphine oxide-based photoradical generator.

Examples of the benzyl ketal-based photoradical generator include 2,2-dimethoxy-1,2-diphenylethane-1-one (Omnirad 651).

Examples of the α-aminoalkylphenone-based photoradical generator include 2-benzyl-2-dimethylamino-1-(4-morpholinophenyl)-butanone-1 (Omnirad 369), 2-methyl-1-[4-(methylthio)phenyl]-2 morpholinopropane-1-one (Omnirad 907), and 2-dimethylamino-2-(4-methyl-benzyl)-1-(4-morpholine-4-yl-phenyl)-butane-1-one (Omnirad 379EG).

Examples of the α-hydroxyalkylphenone-based photoradical generator include 1-hydroxy-cyclohexyl-phenyl-ketone (Omnirad 184).

Examples of the α-hydroxyacetophenone-based photoradical generator include 2-hydroxy-1-{4-[4-(2-hydroxy-2 methyl-propionyl)-benzyl]-phenyl}-2 methyl-propane-1-one (Omnirad 127), and 2-hydroxy-2-methyl-1-phenyl-propane-1-one (Omnirad 1173).

Examples of the acylphosphine oxide-based photoradical generator include 2,4,6-trimethylbenzoyl-diphenyl-phosphine oxide (Omnirad TPO H), and bis(2,4,6-trimethylbenzoyl)-phenylphosphine oxide (Omnirad 819).

The content of the photoradical generator may be 1 mass % or more, 3 mass % or more, or 5 mass % or more and may be 30 mass % or less, 20 mass % or less, or 15 mass % or less, based on the total amount of the curable composition (solid content excluding the solvent).

The ratio of the number of moles of the photoradical generator to the number of moles of the compound A (the number of moles of the photoradical generator/the number of moles of the compound A) may be 0.1 or more, 0.2 or more, or 0.3 or more because the light softening properties are further improved.

### (Curing Accelerator)

The curing accelerator is a component for accelerating the reaction of the compound A and the compound B and includes a component functioning as a catalyst of the curing reaction (catalytic curing agent). Examples of the curing accelerator include an amine compound, an imidazole derivative, quaternary ammonium salt, organometallic salt, and a phosphorus compound.

Examples of the amine compound include dicyandiamide, trimethylamine, triethylamine, tripropylamine, tributylamine, tri-n-octylamine, dimethylethylamine, dimethylpropylamine, dimethylbutylmian, dimethyl-n-octylamine, 1,4-diazabicyclo[2.2.2]octane, 1,8-diazabicyclo[5.4.0]undec-7-ene, benzyldimethylamine, 4-methyl-N,N-dimethylbenzylamine, 2,4,6-tris(dimethylaminomethyl)phenol, and 4-dimethylaminopyridine.

Examples of the imidazole derivative include 1-(1-cyanomethyl)-2-ethyl-4-methyl-1H-imidazole, 2-ethyl-4-methylimidazole, 2-methylimidazole, 2-phenylimidazole, 1-cyanoethyl-2-phenylimidazole, 2-phenyl-4,5-dihydroxymethylimidazole, 2-phenyl-4 methyl-5-hydroxymethylimidazole, 2,4,5-triphenylimidazole, 1-benzyl-2 imidazole, 1,2-dimethylimidazole, and 1-benzyl-2-phenylimidazole.

Examples of the quaternary ammonium salt include tetramethylammonium chloride, tetraethylammonium chloride, tetrabutylammonium chloride, benzyltrimethylammonium chloride, benzyltriethylammonium chloride, benzyltributylammonium chloride, tetramethylammonium bromide, tetraethylammonium bromide, tetrabutylammonium bromide, benzyltrimethylammonium bromide, benzyltriethylammonium bromide, tetramethylammonium iodide, tetraethylammonium iodide, tetrabutylammonium iodide, and benzyltributylammonium iodide.

Examples of the organometallic salt include organometallic salts such as bis(2,4-pentanedionato) zinc (II), zinc octylate, zinc naphthenate, cobalt naphthenate, copper naphthenate, iron acetylacetone, nickel octylate, and manganese octylate.

Examples of the phosphorus compound include tetraphenylphosphonium tetra-p-tolylborate, tetraphenylphosphonium tetraphenylborate, triphenylphosphine, tri-p-tolylphosphine, tris(4-chlorophenyl)phosphine, tris(4-methoxyphenyl) phosphine, tris(2,6-dimethoxyphenyl)phosphine, triphenylphosphine triphenylborane, tetraphenylphosphonium dicyanamide, and tetraphenylphosphonium tetra(4-methylphenyl) borate.

The content of the curing accelerator may be 0.01 mass % or more, 0.1 mass % or more, or 0.5 mass % or more and may be 10 mass % or less, 5 mass % or less, or 2 mass % or less, based on the total amount of the curable composition (solid content excluding the solvent).

The curable composition may further include components (other components) that do not correspond to the compound A, the compound B, the photoradical generator, and the curing accelerator. Examples of other components include a plasticizer; a tackiness imparting agent such as tackifier; an antioxidant; a leuco dye; a sensitizer; an adhesion improver such as a coupling agent; a polymerization inhibitor; a light stabilizer; an antifoaming agent; a filler; a chain transfer agent, a thixotropy imparting agent; a flame retardant; a mold release agent; a surfactant; a lubricant; and an additive such as an antistatic agent. As these additives, known additives can be used. When the curable composition contains other components, the total content of the other components may be 0 to 95 mass %, 0.01 to 50 mass %, or 0.1 to 10 mass % based on the total amount of the curable composition.

The curable composition may be used as a varnish of the curable composition diluted with a solvent. Examples of the solvent include aromatic hydrocarbon such as toluene, xylene, mesitylene, cumene, and p-cymene; aliphatic hydrocarbon such as hexane and heptane; cyclic alkane such as methylcyclohexane; cyclic ether such as tetrahydrofuran and 1,4-dioxane; ketone such as acetone, methyl ethyl ketone, methyl isobutyl ketone, cyclohexanone, and 4-hydroxy-4-methyl-2-pentanone; ester such as methyl acetate, ethyl acetate, butyl acetate, methyl lactate, ethyl lactate, and γ-butyrolactone; carbonic acid ester such as ethylene carbonate and propylene carbonate; and amide such as N,N-dimethylformamide, N,N-dimethylacetamide, and N-methyl-2-pyrrolidone (NMP). The content of the solid content in the varnish, that is, the content of components other than the solvent in the varnish may be 10 to 95 mass %, 15 to 70 mass %, or 20 to 50 mass % based on the total amount of the varnish.

The first laminated body manufacturing step is not particularly limited as long as a first laminated body including the semiconductor wafer 1, the resin layer 3A, and the base material layer 5 in this order is obtained. According to an embodiment, the first laminated body manufacturing step may include preparing the semiconductor wafer 1; disposing a curable composition containing the compound A, the compound B, the photoradical generator, and, as necessary, a curing accelerator that accelerates the reaction of the compound A and the compound B on the semiconductor wafer 1 to form a curable composition layer 3 containing the curable composition (see FIG. 1(a)); disposing the base material layer 5 on the curable composition layer 3 to manufacture a laminated body 10 (see FIG. 1(b)); and curing the curable composition layer 3 by heating the laminated body 10 to form the resin layer 3A containing a cured product of the curable composition (see FIG. 1(c)). It can be said that the resin layer 3A contains the reaction product of the compound A and the compound B (light meltable resin) and the photoradical generator.

According to another embodiment, the first laminated body manufacturing step may include preparing the base material layer 5; disposing the curable composition containing the compound A, the compound B, the photoradical generator, and, as necessary, the curing accelerator that accelerates the reaction of the compound A and the compound B on the base material layer 5 to form the curable composition layer 3 containing the curable composition; bonding the curable composition layer 3 provided on the base material layer 5 to the semiconductor wafer 1, to manufacture the laminated body 10; and heating the laminated body 10 to cure the curable composition layer 3 to form the resin layer 3A containing a cured product of the curable composition.

Examples of the semiconductor wafer 1 include single crystal silicon, polycrystalline silicon, various ceramics, and compound semiconductors such as gallium arsenide. The semiconductor wafer 1 may have a circuit formation surface.

A thickness d1 of the semiconductor wafer 1 may be, for example, 50 to 3,000 μm, 100 to 2,000 μm, or 200 to 1,500 μm.

The curable composition can be prepared, for example, by a method including mixing or kneading the respective components described above. Mixing and kneading can be performed by appropriately combining a disperser such as a normal stirrer, a mixer, three rolls, a ball mill, or a bead mill.

The method for disposing the curable composition on the semiconductor wafer is not particularly limited. However, examples thereof include a method in which the curable composition is applied onto the semiconductor wafer 1 using a spin coater, a bar coater, or the like, and a method in which the curable composition is molded into a film, and the molded curable composition film is attached (transferred) to the semiconductor wafer 1. The curable composition film may be in a semi-cured state (B-stage state) before bonding the curable composition film and the semiconductor wafer 1. The curable composition may be disposed, for example, on the circuit formation surface of the semiconductor wafer 1.

The thickness of the curable composition layer 3 may be, for example, 10 to 1,000 μm, 30 to 750 μm, or 50 to 500 μm.

Examples of the base material layer 5 include a polyolefin film of polyethylene (PE), polypropylene (PP), or the like; a polyester film such as polyethylene terephthalate (PET), polybutylene terephthalate (PBT), and polyethylene naphthalate; a polyvinyl chloride (PVC) film; a polyimide (PI) film; a polyphenylene sulfide (PPS) film; an ethylene-vinyl acetate (EVA) film; and a polytetrafluoroethylene (PTFE) film.

The thickness of the base material layer 5 may be, for example, 10 to 1,000 μm, 30 to 500 μm, or 50 to 200 μm.

The curable composition can form a cured product of the curable composition, for example, by heating. The reaction of the compound A and the compound B proceeds by heating the curable composition. At this time, the curing accelerator can accelerate the reaction. The reaction product (light meltable resin) of the compound A and the compound B may be, for example, a compound (polymer) having a structure represented by the following formula. Meanwhile, the photoradical generator is less involved in the reaction, and the cured product of the curable composition may contain a reaction product (light meltable resin) of the compound A and the compound B and the photoradical generator.

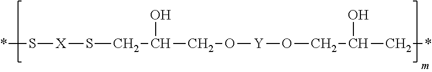

In the formula, X represents a first linking group, and Y represents a second linking group. m represents an integer of 1 or more. m may be, for example, 50 or more, 100 or more, 500 or more, or 1,000 or more. * represents a bond.

The heating temperature of the laminated body 10 (the curable composition layer 3) may be, for example, 0° C. to 200° C. and may be 30° C. to 150° C., or 60° C. to 100° C. The heating time of the curable composition may be, for example, 0.1 to 168 hours and may be 72 hours or less, 48 hours or less, or 24 hours or less.

The resin layer 3A may be in a (completely) cured state (C-stage state). The thickness of the resin layer 3A may be, for example, 10 to 1,000 μm, 30 to 500 μm, or 50 to 200 μm.

In this manner, the first laminated body 10A including the semiconductor wafer 1, the resin layer 3A including the light meltable resin, and the base material layer 5 in this order can be manufactured.

### <Second Laminated Body Manufacturing Step>

In this step, the semiconductor wafer 1 of the first laminated body 10A is subjected to backside grinding to manufacture a second laminated body 20 (see FIG. 1(d)). The base material layer 5 and the resin layer 3A of the first laminated body 10A can be regarded as a back grinding tape 7 including the base material layer 5 and the resin layer 3A provided on the base material layer 5. In the first laminated body 10A, it can be said that the back grinding tape 7 is attached to the semiconductor wafer 1, and the first laminated body 10A can be subjected to the backside grinding (back grinding) step.

The backside grinding of the semiconductor wafer 1 can be performed using a general back grinder. As illustrated in FIG. 1(d), the surface of the semiconductor wafer 1 opposite to the surface to which the back grinding tape 7 is attached, for example, by using a grinder 9, to thin the thickness of the semiconductor wafer 1.

A thickness d1A of a semiconductor wafer (a semiconductor wafer 1A) subjected to backside grinding is thinner than the thickness d1 of the semiconductor wafer 1 and may be, for example, 10 to 1,000 μm, 20 to 900 μm, or 30 to 800 μm.

In this manner, the second laminated body 20 including the semiconductor wafer 1A, the resin layer 3A including the light meltable resin, and the base material layer 5 in this order can be manufactured.

### <Third Laminated Body Manufacturing Step>

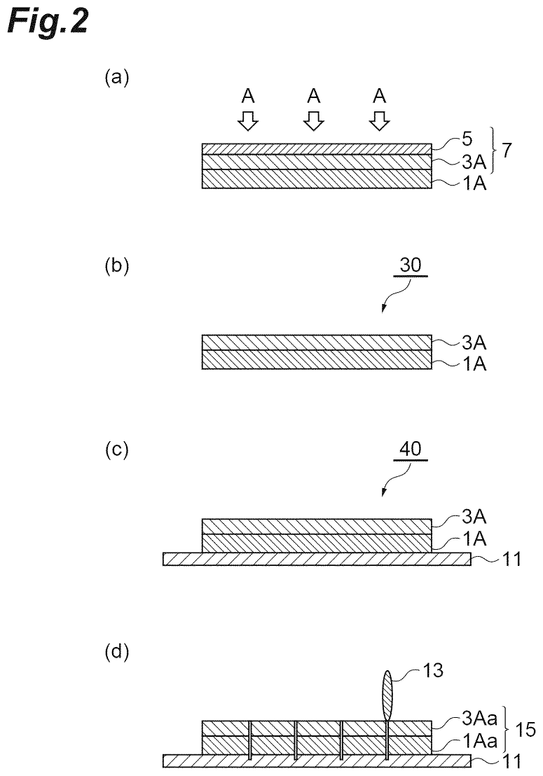

In this step, the base material layer 5 of the second laminated body 20 is removed to manufacture a third laminated body 30 including the semiconductor wafer 1A and the resin layer 3A. This step may be irradiating the resin layer 3A of the second laminated body 20 with light A to remove the base material layer 5 (see FIG. 2(a)). Since the light meltable resin included in the resin layer 3A is reduced in molecular weight due to the irradiation with the light A to obtain a gel or liquid, the base material layer 5 can be easily removed from the second laminated body 20.

The mechanism by which the light meltable resin is reduced in molecular weight (melted) is not necessarily clear, but for example, the following mechanism is considered. However, the present invention is not limited to these mechanisms. The light meltable resin includes a compound having a disulfide bond (a reaction product of the compound A and the compound B). When the light meltable resin included in the resin layer is irradiated with light, disulfide bonds in the light meltable resin are decomposed (cleaved) to generate a thiyl radical. At this time, when the photoradical generator (intramolecular cleavage type photoradical generator) is present, the thiyl radical and the photoradical generator react with each other, and the thiyl radical is capped by the photoradical generator. As a result, it is considered that the molecular weight of the compound having a disulfide bond is reduced, and the cured product is light-softened (light-melted). As another mechanism, it is also conceivable that a light-induced radical caused by a photoradical generator (intramolecular cleavage type photoradical generator) directly reacts with a disulfide bond, to form a light-induced radical-thioether bond and generate a thiyl radical, the thiyl radical reacts with another light-induced radical, the molecular weight of the compound having a disulfide bond itself is reduced, and a photocured product is softened. It can be said that the reaction in which the disulfide bond is cleaved is an irreversible reaction.

The light A with which the resin layer 3A is irradiated may be, for example, ultraviolet light or visible light. The wavelength of the light A can be appropriately selected according to, for example, the type of the photoradical generator to be used. The wavelength of the light A may be, for example, 150 to 830 nm. The light A may include, for example, light having a wavelength of 405 nm or a wavelength of 365 nm.

The irradiation with the light A can be performed, for example, using a light irradiation device under the condition that the irradiation amount is 1,000 mJ/cm² or more. The irradiation amount can be appropriately set according to, for example, the wavelength of the light A. The irradiation amount may be, for example, 3,000 mJ/cm² or more, 5,000 mJ/cm² or more, or 10,000 mJ/cm² or more and may be 100,000 mJ/cm² or less, 80,000 mJ/cm² or less, or 60,000 mJ/cm² or less.

The irradiation amount means a product of illuminance and irradiation time (seconds). Examples of the light source for irradiation with ultraviolet light or visible light include a low-pressure mercury lamp, an intermediate-pressure mercury lamp, a high-pressure mercury lamp, a metal halide lamp, and an LED lamp.

The irradiation with the light A may be performed under a condition that the resin layer 3A in the vicinity of the interface between the resin layer 3A and the base material layer 5 is light-melted from the base material layer 5 side (via the base material layer 5) and under a condition that the entire resin layer 3A is not light-melted. As a result, the base material layer 5 can be easily removed, and the remaining resin layer 3A can be used as a protective layer of the semiconductor wafer 1A after the next step.

This step may be removing the base material layer 5 without irradiating the resin layer 3A of the second laminated body 20 with light A. Examples of such a method include a method of bonding a support tape to the base material layer 5 and drawing the support tape to peel the base material layer 5 from the resin layer 3A.

In this manner, the third laminated body 30 including the semiconductor wafer 1A and the resin layer 3A including the light meltable resin can be manufactured.

### <Resin Layer Piece-Including Semiconductor Chip Manufacturing Step>

In this step, the third laminated body 30 is diced to manufacture a singulated resin layer piece-including semiconductor chip 15.

The resin layer piece-including semiconductor chip manufacturing step may include, for example, preparing a laminated body 40 including a dicing tape 11, the semiconductor wafer 1A, and the resin layer 3A in this order (see FIG. 2(c)) and dicing at least the semiconductor wafer 1A and the resin layer 3A in the laminated body 40 to obtain the singulated resin layer piece-including semiconductor chip 15 (see FIG. 2(d)).

Examples of the dicing tape 11 include plastic films such as a polytetrafluoroethylene film, a polyethylene terephthalate film, a polyethylene film, a polypropylene film, a polymethylpentene film, and a polyimide film. Also, the dicing tape may be subjected to a surface treatment such as primer application, a UV treatment, a corona discharge treatment, a polishing treatment, or an etching treatment as necessary. The dicing tape may have tackiness. Such a dicing tape may be a dicing tape obtained by imparting tackiness to the plastic film or a dicing tape obtained by providing a pressure sensitive adhesives layer on one surface of the plastic film. The pressure sensitive adhesive layer may be formed of an ultraviolet-curable or non-ultraviolet-curable pressure sensitive adhesive and is not particularly limited as long as the pressure sensitive adhesive layer has sufficient adhesive strength so that a semiconductor element does not scatter during dicing, and the pressure sensitive adhesive layers known in the related art can be used.

The thickness of the dicing tape 11 may be, for example, 10 to 1,000 μm, 30 to 500 μm, or 50 to 300 μm.

The laminated body 40 can be obtained by attaching the dicing tape 11 to the semiconductor wafer 1A of the third laminated body 30.

Subsequently, in the laminated body 40, at least the semiconductor wafer 1A and the resin layer 3A (and a part of the dicing tape 11) are diced to be singulated into individual pieces. The dicing may be, for example, dicing by a dicing blade 13. The dicing by the dicing blade 13 can be performed using a commercially available device. The dicing by the dicing blade 13 is performed, for example, on the semiconductor wafer 1A and the resin layer 3A in a cutting pattern forming a lattice shape in plan view.

From the viewpoint of suppressing a temperature rise at a contact portion between the semiconductor wafer 1A or the resin layer 3A and the dicing blade 13, the dicing by the dicing blade 13 is generally performed while cooling water (cutting water) is poured on the contact portion. Since the light meltable resin is a water-insoluble resin, the resin layer 3A can sufficiently suppress dissolution of the resin layer due to cooling water (cutting water) and can act as a protective layer for preventing a cut product (debris) from adhering to the circuit formation surface of the semiconductor wafer.

The dicing may be, for example, plasma dicing, stealth dicing, or laser dicing, instead of the blade dicing.

In this manner, the semiconductor wafer 1A and the resin layer 3A each are singulated, and the resin layer piece-including semiconductor chip 15 including semiconductor chips 1Aa and resin layer pieces 3Aa can be obtained.

The shape of the semiconductor chip 1Aa in plan view may be, for example, a square or a rectangle. The area of the semiconductor chip 1Aa may be, for example, 1 to 250 mm², 4 to 200 mm², or 9 to 150 mm². The length of one side of the semiconductor chip 1Aa may be 1 mm or more, 2 mm or more, or 3 mm or more and may be 20 mm or less, 18 mm or less, or 15 mm or less. The thickness of the semiconductor chip 1Aa may be similar to the thickness of the semiconductor wafer 1A.

The method for manufacturing the semiconductor device according to the present embodiment may further include a resin layer piece removing step of irradiating the resin layer piece 3Aa of the resin layer piece-including semiconductor chip 15 with light B to remove the resin layer piece 3Aa from the resin layer piece-including semiconductor chip 15, an ultraviolet irradiation step of irradiating the pressure sensitive adhesive layer of the dicing tape 11 with ultraviolet light, a pickup step of picking up the semiconductor chip 1Aa, and a semiconductor chip bonding step of bonding the picked-up semiconductor chip 1Aa and a support member 19 via an adhesive layer 21 (die-bonding film or the like) by thermocompression bonding, a thermal curing step of thermally curing the adhesive layer 21, and the like.

### <Resin Layer Piece Removing Step>

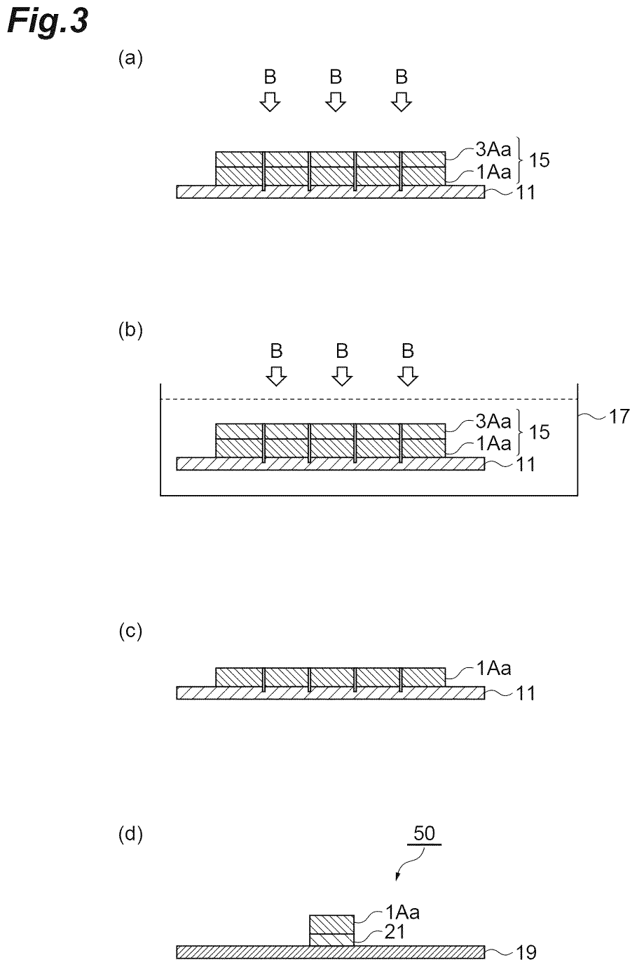

In this step, the resin layer pieces 3Aa of the resin layer piece-including semiconductor chip 15 are irradiated with the light B to remove the resin layer pieces 3Aa from the resin layer piece-including semiconductor chip 15 (see FIG. 3(a)). Since the light meltable resin included in the resin layer piece 3Aa is reduced in molecular weight due to the irradiation with the light B to obtain a gel or liquid, the resin layer piece 3Aa can be easily removed from the resin layer piece-including semiconductor chip 15.

The light B with which the resin layer pieces 3Aa are irradiated may be the same as the light A with which the resin layer 3A are irradiated and may be, for example, ultraviolet light or visible light. The wavelength of the light B can be appropriately selected according to, for example, the type of the photoradical generator to be used. The wavelength of the light B may be, for example, 150 to 830 nm. The light B may include, for example, light having a wavelength of 405 nm or a wavelength of 365 nm.

The irradiation with the light B can be performed, for example, using a light irradiation device under the condition that the irradiation amount is 1,000 mJ/cm² or more. The irradiation amount can be appropriately set according to, for example, the wavelength of the light B. The irradiation amount may be, for example, 3,000 mJ/cm² or more, 5,000 mJ/cm² or more, or 10,000 mJ/cm² or more and may be 100,000 mJ/cm² or less, 80,000 mJ/cm² or less, or 60,000 mJ/cm² or less.

According to an embodiment, the resin layer piece removing step may be removing the resin layer pieces 3Aa from the resin layer piece-including semiconductor chip 15 using an aqueous solvent. Since the light meltable resin included in the resin layer piece 3Aa is reduced in molecular weight due to the irradiation with the light to obtain a gel or liquid, the resin layer piece 3Aa can be sufficiently removed by being washed with the aqueous solvent.

Examples of the aqueous solvent include water and a mixed solvent of water and a hydrophilic organic solvent. In the mixed solvent of water and the hydrophilic organic solvent, the ratio of water can be, for example, 80 mass % or more. For example, a pH adjusting agent may be added to the aqueous solvent.

The aqueous solvent may be water. Examples of the water include tap water, natural water, purified water, distilled water, ion-exchanged water, pure water, and ultrapure water (Milli-Q water or the like). The Milli-Q water means ultrapure water obtained by a Milli-Q water manufacturing device of Merck Millipore (Merck). Since impurities are reduced, the water may be purified water, distilled water, ion-exchanged water, pure water, or ultrapure water.

Examples of the hydrophilic organic solvent include alcohols such as methanol, ethanol, 2-propanol, and 1,2-propanediol; and glycol ether such as ethylene glycol monomethyl ether, propylene glycol monomethyl ether, ethyl cellosolve, propylene glycol monopropyl ether, propylene glycol monoisopropyl ether, butyl cellosolve, ethylene glycol monoisobutyl ether, propylene glycol monobutyl ether, diethylene glycol dimethyl ether, diethylene glycol diethyl ether, and dipropylene glycol monomethyl ether.

Examples of the pH adjusting agent include inorganic acid, inorganic base, organic acid, and organic base. Examples of the inorganic acid include nitric acid, sulfuric acid, hydrochloric acid, phosphoric acid, and boric acid. Examples of the inorganic base include sodium hydroxide, potassium hydroxide, and calcium hydroxide. Examples of the organic acid include formic acid, acetic acid, propionic acid, butyric acid, acrylic acid, benzoic acid, and picolinic acid. Examples of the organic base include primary amine, secondary amine, tertiary amine, tetramethylammonium hydroxide, tetraethylammonium hydroxide, and an imidazole-based compound.

According to an embodiment, the resin layer piece removing step may be irradiating the resin layer pieces 3Aa with the light B from the resin layer piece-including semiconductor chip 15 in an aqueous solvent 17 (see FIG. 3(b)). The light meltable resin included in the resin layer piece 3Aa is reduced in molecular weight due to the irradiation with the light to obtain a gel or liquid. Therefore, by irradiating the resin layer pieces 3Aa with the light B in the aqueous solvent 17, a gel or liquid flows out to the aqueous solvent 17, so that the resin layer pieces 3Aa can be efficiently removed.

In this manner, the plurality of semiconductor chips 1Aa in which adhesion of cut products (debris) is sufficiently suppressed can be obtained from the semiconductor wafer 1A (see FIG. 3(c)).

### <Ultraviolet Irradiation Step>

When the pressure sensitive adhesive layer of the dicing tape 11 is configured with an ultraviolet curable pressure sensitive adhesive, the method for manufacturing the semiconductor device may include the ultraviolet irradiation step. In this step, the pressure sensitive adhesive layer is irradiated with ultraviolet light. In the ultraviolet irradiation, the wavelength of the ultraviolet light may be 200 to 400 nm. In the ultraviolet irradiation condition, the illuminance and the irradiation amount may be in a range of 30 to 240 m W/cm² and a range of 50 to 500 mJ/cm², respectively.

### <Pickup Step>

In this step, the semiconductor chips 1Aa pushed up by the needle from the dicing tape 11 side are sucked by the suction collet and picked up from the dicing tape 11 while separating the singulated semiconductor chips 1Aa from each other.

The ultraviolet irradiation step and the pickup step may be performed after the resin layer piece removing step or may be performed before the resin layer piece removing step.

### <Semiconductor Chip Bonding Step>

In this step, the picked-up semiconductor chip 1Aa and the support member 19 are bonded to each other by thermocompression bonding via the adhesive layer 21 (die-bonding film or the like). As the die-bonding film, a die-bonding film used in the art can be used. The plurality of semiconductor chips 1Aa may be bonded to the support member 19.

The heating temperature in the thermocompression bonding may be, for example, 80° C. to 160° C. The load in thermocompression bonding may be, for example, 5 to 15 N. The heating time in the thermocompression bonding may be, for example, 0.5 to 20 seconds.

### <Thermal Curing Step>

In this step, the adhesive layer 21 is thermally cured. The heating temperature can be appropriately changed depending on the constituents of the die-bonding film. The heating temperature may be, for example, 60° C. to 200° C., 90° C. to 190° C., or 120° C. to 180° C. The heating time may be 30 minutes to five hours, one to three hours, or two to three hours. The temperature or the pressure may be stepwise changed.

In this manner, a semiconductor device 50 (see FIG. 3(d)) including the semiconductor chip 1Aa, the support member 19 on which the semiconductor chip 1Aa is mounted, and the adhesive layer 21 provided between the semiconductor chip 1Aa and the support member 19 and bonding the semiconductor chip 1Aa and the support member 19 can be manufactured.

According to the method for manufacturing a semiconductor device of the present disclosure, a semiconductor wafer can be sufficiently protected, and a base material layer can be easily removed.

### REFERENCE SIGNS LIST

1, 1A: semiconductor wafer, 1Aa: semiconductor chip, 3: curable composition layer, 3A: resin layer, 3Aa: resin layer piece, 5: base material layer, 7: back grinding tape, 9: grinder, 10: laminated body, 10A: first laminated body, 11: dicing tape, 13: dicing blade, 15: resin layer piece-including semiconductor chip, 17: aqueous solvent, 19: support member, 20: second laminated body, 21: adhesive layer, 30: third laminated body, 40: laminated body, 50: semiconductor device

1. A method for manufacturing a semiconductor device, the method comprising:
a first laminated body manufacturing step of manufacturing a first laminated body comprising, in this order, a semiconductor wafer, a resin layer containing a resin in which the molecular weight is reduced by irradiation with light, and a base material layer;
a second laminated body manufacturing step of manufacturing a second laminated body by performing backside grinding on the semiconductor wafer of the first laminated body; and
a third laminated body manufacturing step of manufacturing a third laminated body comprising a semiconductor wafer subjected to backside grinding and the resin layer by removing the base material layer of the second laminated body.

2. The method for manufacturing a semiconductor device according to claim 1, wherein the third laminated body manufacturing step is irradiating the resin layer of the second laminated body with light to remove the base material layer.

3. The method for manufacturing a semiconductor device according to claim 1, further comprising: a resin layer piece-including semiconductor chip manufacturing step of dicing the third laminated body to manufacture a singulated resin layer piece-including semiconductor chip.

4. The method for manufacturing a semiconductor device according to claim 1, wherein the resin in which the molecular weight is reduced by irradiation with light is a reaction product of a compound A having a disulfide bond and two or more thiol groups and a compound B having two or more functional groups capable of reacting with a thiol group.

5. The method for manufacturing a semiconductor device according to claim 4, the resin layer further comprising a photoradical generator.

6. The method for manufacturing a semiconductor device according to claim 1, wherein the first laminated body manufacturing step comprises:
preparing the semiconductor wafer;
disposing a curable composition comprising a compound A having a disulfide bond and two or more thiol groups, a compound B having two or more functional groups capable of reacting with a thiol group, and a photoradical generator, on the semiconductor wafer to form a curable composition layer comprising the curable composition;
disposing the base material layer on the curable composition layer to manufacture a laminated body; and
curing the curable composition layer by heating the laminated body to form the resin layer including a cured product of the curable composition.
